(19) United States
(12) Patent Application Publication
(10) Pub. No.: US 2015/0028449 A1
(43) Pub. Date: Jan. 29, 2015

(54) NANOPARTICLES FOR MAKING SUPERCAPACITOR AND DIODE STRUCTURES

(71) Applicant: International Business Machines Corporation, Armonk, NY (US)

(72) Inventors: James W. Adkisson, Jericho, VT (US); John J. Ellis-Monaghan, Grand Isle, VT (US); Jeffrey P. Gambino, Westford, VT (US); Kirk D. Peterson, Jericho, VT (US); Jed H. Rankin, Richmond, VT (US)

(73) Assignee: International Business Machines Corporation, Armonk, NY (US)

(21) Appl. No.: 13/950,323

(22) Filed: Jul. 25, 2013

(51) Int. Cl. H01L 49/02; H01L 21/762

(52) U.S. Cl. CPC H01L 28/60; H01L 21/76224; B82Y 40/00
USPC 257/532; 438/381; 977/773

(57) ABSTRACT

Structures and methods of making a supercapacitor may include a first electrode comprising a first conductive plate and a 3-dimensional (3D) aggregate of sintered nanoparticles electrically connected one to another and to the first conductive plate. The supercapacitor may also include a dielectric formed on surfaces of the 3D aggregate of sintered nanoparticles. The supercapacitor may further include a second electrode comprising a solid second conductor that fills interstices between surfaces of the dielectric and electrically connects to a second conductive plate of a solid second conductor, disposed above an outermost portion of the dielectric.

### BACKGROUND

1. Field of the Invention

The present disclosure relates to structures and methods of making a supercapacitor with nanoparticles that does not employ an electrolyte. The present disclosure also relates to structures and methods of making a diode with nanoparticles to provide a p-n junction of a large surface area in a small volume.

2. Description of Related Art

Capacitors store electrical energy in an electric field disposed within a dielectric separating two conductive electrodes or plates. Typically, ceramic capacitors have a ceramic dielectric that separates two metal foil sheets, while film capacitors are identified by their dielectrics, e.g., polypropylene, polyethylene terephthalate, or polyfluoro-ethylene. The capacitance, C, of conventional plate capacitors varies directly with the area, A, of the electrodes and inversely with the thickness, d, of the dielectric, i.e., C=∈A/d, where ∈ equals the permittivity of the dielectric material.

In semiconductor integrated circuits, a planar capacitor may use a semiconductor as one of the electrodes to form a metal-insulator-semiconductor (MIS) capacitor. To reduce the footprint, i.e., the surface area, of capacitors in semiconductors, trench capacitors orient the dielectric and electrodes of the capacitor vertically to the semiconductor substrate. Various configurations of stacked capacitors, used frequently in dynamic random access memories (DRAMs), can deposit multiple alternating layers of dielectric and electrode in either horizontal or vertical orientations to the semiconductor substrate.

Electrolytic capacitors are polarized and have a metal anode covered by an oxide layer, which forms the dielectric. The second electrode or cathode is frequently a liquid electrolyte, although a solid conductive polymer can also be used as an electrolyte. The anode may be roughened or sintered to increase surface area and the relatively high permittivity of the oxide dielectric layer may provide electrolytic capacitors with a higher capacitance per unit volume than those of conventional ceramic or film capacitors.

A double-layer electrochemical capacitor, frequently called a supercapacitor, may have an even higher capacitance per unit volume value than electrolytic capacitors. However, these double-layer electrochemical capacitors lack the solid dielectric material of ceramic, film and electrolytic capacitors. Instead, an electrolyte connects the two polarized electrodes of the electrochemical capacitor. The electrochemical capacitor stores electrical charge by two storage mechanisms: double-layer capacitance, which separates charges in a Helmholtz double layer by a few Angstroms at the interface between the surface of a conductive electrode and the electrolyte solution; and pseudocapacitance resulting from redox reactions, electrosorbtion or intercalation on the surface of the electrode or by specifically adsorbed ions that result in a reversible faradaic charge-transfer. The double-layer capacitance and the pseudocapacitance of the double-layer electrochemical capacitor may, in some cases, combine to provide a supercapacitor, having a capacitance per unit volume equal to or greater than 1 Farad/cm³.

A diode is a two-terminal electronic component with asymmetric current transfer, i.e., low resistance to current flow in one direction and high resistance to current flow in the opposite direction. A semiconductor diode comprises two adjacent regions of a crystalline semiconductor, in which one region, called an n-type, contains an excess of negative electrical charge carriers, i.e., electrons, and a second region, called a p-type, contains an excess of positive electrical charge carriers, i.e., holes. When the two regions are attached together, a momentary flow of electrons occurs from the n-type region to the p-type region, creating a reverse bias potential, i.e., the n-type region has a positive potential with respect to the negative potential of the p-type region. Subsequently, the diode will allow electrons to flow from the n-type semiconductor, called the cathode, to the p-type semiconductor, called the anode, when the reverse bias potential is overcome by an external voltage placed across the two terminals of the diode in the opposite direction, i.e., the potential of the cathode is brought negative relative to the anode. The amount of current that may be passed by a forward-biased diode is proportional to the surface area of the p-n junction.

There remains a need for a supercapacitor that does not employ an electrolyte and that may use semiconductor integrated circuit processes of fabrication, and for a diode having a large forward current capacity that may use semiconductor integrated circuit processes of fabrication.

### SUMMARY

In view of the foregoing, the disclosure may provide a structure for a supercapacitor. The supercapacitor may include a first electrode comprising a first conductive plate and a 3-dimensional (3D) aggregate of sintered nanoparticles disposed above the first conductive plate. Each of the sintered nanoparticles may retain a similar shape and electrically connect one to another and to the first conductive plate. The supercapacitor may also include a dielectric formed on surfaces of the 3D aggregate of sintered nanoparticles and on the first conductive plate. The supercapacitor may further include a second electrode comprising a solid second conductor filling interstices between surfaces of the dielectric and electrically connecting to a second conductive plate of the solid second conductor, disposed above an outermost portion of the dielectric.

The disclosure may provide a method of making a supercapacitor in a semiconductor integrated circuit. The method may include etching a trench through an oxide layer to a top surface of a doped silicon (Si) substrate. The method may also include filling the trench with doped Si nanoparticles of the same composition as the doped Si substrate. The method may further include annealing the doped Si nanoparticles to form a 3-dimensional (3D) aggregate of annealed doped Si nanoparticles, in which each of the annealed doped Si nanoparticles retains a similar shape and electrically connects one to another to the doped Si substrate, forming a first electrode. The method may yet further include forming an oxide dielectric on surfaces of the annealed doped Si nanoparticles and on portions of a top surface of the first doped substrate. Finally, the method may include depositing a chemical vapor of Si and a dopant to fill interstices between surfaces of the oxide dielectric with doped Si and to form a layer of the doped Si on a top portion of the oxide dielectric between walls of the trench, forming a solid second conductor, as a second electrode of the supercapacitor.

The disclosure may provide a method of making a diode in a semiconductor integrated circuit. The method may include etching a trench within a doped silicon (Si) substrate of a first charge-type. The method may also include forming a sidewall on the trench with doped Si of a second charge-type. The method may further include filling the trench with the sidewall with a mixture of first doped Si nanoparticles of the first charge-type and of second doped Si nanoparticle of the second charge-type. Finally, the method may include annealing and reflowing the mixture of the first doped Si nanoparticles and the second doped Si nanoparticles to form: a first 3-dimensional (3D) region of annealed, reflowed doped Si of the first charge-type electrically connected to the doped Si substrate; a second 3D region of annealed, reflowed doped Si of the second charge-type electrically connected to the sidewall; and a surface portion of the first 3D region of the doped Si of the first charge-type being annealed and electrically connected to a surface portion of the second 3D region of the doped Si of the second-charge type, forming a p-n junction of the diode.

### BRIEF DESCRIPTION OF THE DRAWINGS

The structures and methods of making structures herein will be better understood from the following detailed description with reference to the drawings, which are not necessarily drawn to scale and in which:

FIG. 1 is a schematic diagram illustrating deposition of metal nanoparticles on a first conductive plate in the making of a supercapacitor;

FIG. 2 is a schematic diagram illustrating the sintering of the metal nanoparticles on the first conductive plate in the making of a supercapacitor;

FIG. 3 is a schematic diagram illustrating the forming of a dielectric on surfaces of the sintered metal nanoparticles in the making of a supercapacitor;

FIG. 4 is a schematic diagram illustrating the forming of a second conductive plate on an outermost portion of the dielectric in the making of a supercapacitor;

FIG. 5 is a schematic diagram illustrating the filling of interstices between surfaces of the dielectric that electrically connect to an overlying second conductive plate, forming a solid second conductor, in the making of a supercapacitor;

FIG. 6 is a schematic diagram illustrating the etching of a trench through an oxide layer to a top surface of a doped Si substrate, and filling the trench with doped Si nanoparticles in the making of a supercapacitor using semiconductor integrated circuit processes;

FIG. 7 is a schematic diagram illustrating the annealing of the doped Si nanoparticles to form a 3-dimensional aggregate of annealed doped Si particles in the making of a supercapacitor using semiconductor integrated circuit processes;

FIG. 8 is a schematic diagram illustrating the forming of an oxide dielectric on surfaces of the annealed doped Si nanoparticles in the making of a supercapacitor using semiconductor integrated circuit processes;

FIG. 9 is a schematic diagram illustrating the depositing, by chemical vapor deposition, of doped Si to fill interstices between surfaces of the oxide dielectric and to cover a top portion of the oxide dielectric, forming a solid second conductor, in the making of a supercapacitor using semiconductor integrated circuit processes;

FIG. 10 is a schematic diagram illustrating the etching of a trench within a doped Si substrate, and filling the trench with doped Si nanoparticles in the making of a supercapacitor using semiconductor integrated circuit processes;

FIG. 11 is a schematic diagram illustrating the annealing of the doped Si nanoparticles to form a 3-dimensional aggregate of annealed doped Si particles in the making of a supercapacitor using semiconductor integrated circuit processes;

FIG. 12 is a schematic diagram illustrating the forming of an oxide dielectric on surfaces of the annealed doped Si nanoparticles, of sidewalls and a bottom of the trench within the doped Si substrate, and of a top of the doped Si substrate in the making of a supercapacitor using semiconductor integrated circuit processes;

FIG. 13 is a schematic diagram illustrating the depositing, by chemical vapor deposition, of doped Si to fill interstices between surfaces of the oxide dielectric and to cover sidewalls and a bottom of the trench, and a top portion of the doped Si substrate, forming a solid second conductor, in the making of a supercapacitor using semiconductor integrated circuit processes;

FIG. 14 is a schematic diagram illustrating the etching of a trench within a doped silicon (Si) substrate of a first charge-type, and forming a sidewall on the trench with doped Si of a second charge-type in the making of a diode using semiconductor integrated circuit processes;

FIG. 15 is a schematic diagram illustrating the filling of the trench with the sidewall with a mixture of doped Si nanoparticles of the first charge-type and of the second charge-type in the making of a diode using semiconductor integrated circuit processes; and

FIG. 16 is a schematic diagram illustrating the annealing and reflowing of the mixture of the doped Si nanoparticles of the first charge-type and of the second charge-type to form an intermingled 3D region of annealed, reflowed doped Si of the first charge-type and annealed, reflowed doped Si of the second charge-type in the making of a diode using semiconductor integrated circuit processes.

### DETAILED DESCRIPTION

The exemplary structures and methods of making the structures of the disclosure and their various features and advantageous details are explained more fully with reference to the non-limiting exemplary structures and methods of making the structures that are illustrated in the accompanying drawings and detailed in the following description. It should be noted that the features illustrated in the drawings are not necessarily drawn to scale. Descriptions of well-known materials, components, and processing techniques are omitted so as to not unnecessarily obscure the exemplary methods, systems and products of the disclosure. The examples used herein are intended to merely facilitate an understanding of ways in which the exemplary structures and methods of making the structures of the disclosure may be practiced and to further enable those of skill in the art to practice the exemplary structures and methods of making the structures of the disclosure. Accordingly, the examples should not be construed as limiting the scope of the exemplary structures and methods of making the structures of the disclosure.

As stated above, there remains a need for a supercapacitor that does not employ an electrolyte and that may use semiconductor integrated circuit processes of fabrication, and for a diode having a large forward current capacity that may use semiconductor integrated circuit processes of fabrication. In addition, a beneficial aspect of a supercapacitor may include plates and a dielectric that comprise solid materials, rather than the liquid electrolyte of a conventional double-layer electrochemical supercapacitor. Furthermore, a non-polarized supercapacitor may avoid the disadvantage of polarized electrolytic capacitors, which may explode when negative voltages are applied to an anode or positive voltages to a cathode.

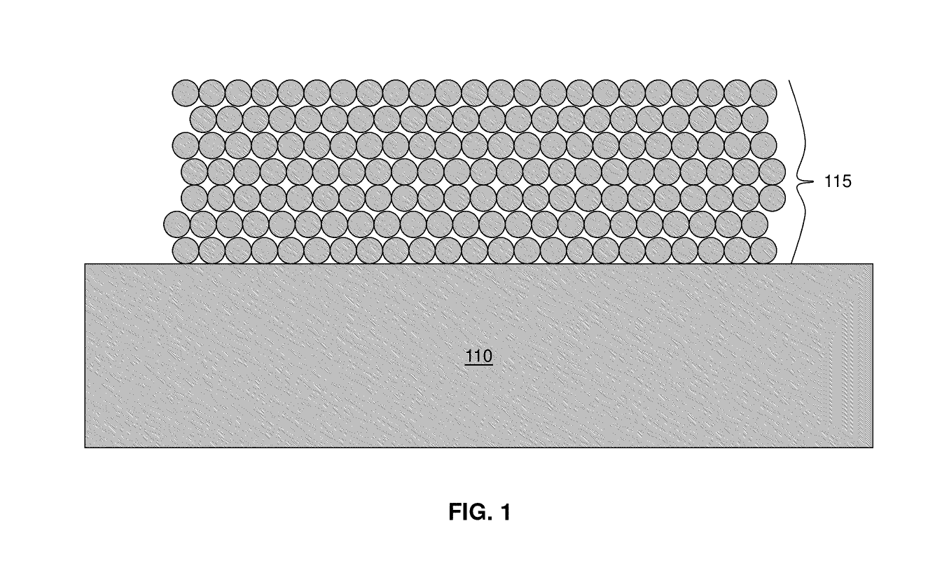

Referring to FIG. 1, a method of making a supercapacitor, having a capacitance per unit volume approaching, equal to or greater than 1 F/cm³ in some cases, may include depositing metal nanoparticles 115 on a first conductive plate 110. The metal nanoparticles 115 may have roughly similar shapes including any one of: spheres, ellipsoids, rods, cubes, and polyhedrons, and may have a longest axis ranging from 5 nm to 50 nm in length. The metal nanoparticles 115 may comprise metals and metal alloys including but not limited to any of: aluminum (Al), copper (Cu), silver (Ag), titanium (Ti), tantalum (Ta), nickel (Ni), and tungsten (W).

The first conductive plate 110, upon which the metal nanoparticles 115 are deposited, may comprise one of: silicon (Si), doped Si, polysilicon, doped polysilicon, and a metal or metal alloy including any of: aluminum (Al), copper (Cu), silver (Ag), titanium (Ti), tantalum (Ta), nickel (Ni), and tungsten (W).

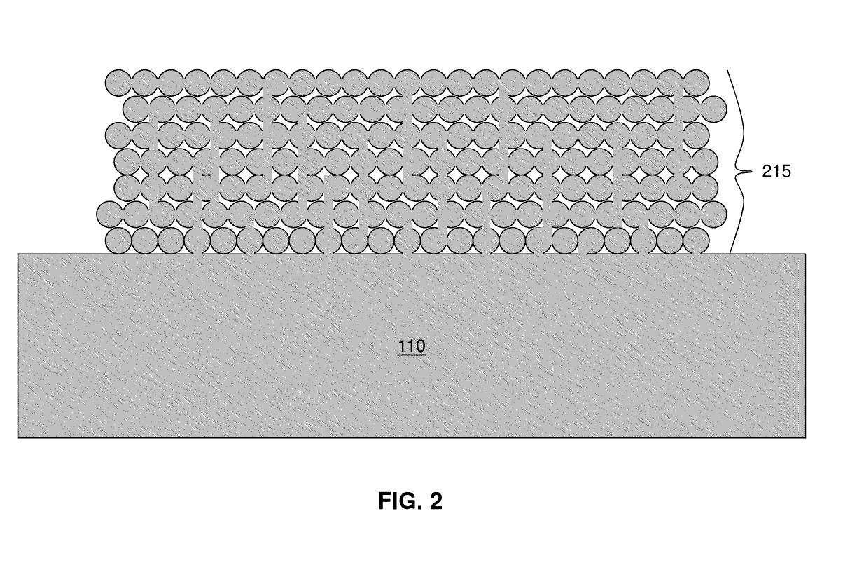

Referring to FIG. 2, in making the supercapacitor, the metal nanoparticles 115 may be heated in a non-oxidizing medium to form a 3-dimensional (3D) aggregate of sintered metal nanoparticles 215, in which each of the sintered metal nanoparticles 215 retains a shape similar to that, which was deposited. Each sintered metal nanoparticle may connect physically to surrounding sintered metal nanoparticles 215 and electrically from one sintered metal nanoparticle to another through the 3D aggregate of sintered nanoparticles 215 to the first conductive plate 110, forming a first electrode of the supercapacitor. As known to one of ordinary skill in the art, the temperature used to sinter the sintered metal nanoparticles 215 may approach the melting point of the metal nanoparticles 115. The sintering temperature for the sintered metal nanoparticles 215 may be less than the melting point of the first conductive plate 110. For example, in making a discrete supercapacitor component, aluminum (Al) nanoparticles may be sintered at a temperature less than the melting point of Al, i.e., 660.23° C., to form a 3D aggregate of sintered aluminum nanoparticles electrically connected to a first conductive plate 110 of copper (Cu) with a melting point of 1084° C.

In making a supercapacitor component for a semiconductor integrated circuit device, e.g., a capacitor of a single bit of dynamic random access memory (DRAM) or a capacitor in a back end of line (BEOL) process for a semiconductor device, the metal nanoparticles 115 may comprise semiconductor compatible metals and metal alloys including any of: aluminum (Al), copper (Cu), silver (Ag), titanium (Ti), tantalum (Ta), nickel (Ni), and tungsten (W). The sintering temperature for the semiconductor compatible metal nanoparticles 115 may also be less than the melting point of the semiconductor material, e.g., silicon or germanium. For example, aluminum nanoparticles may be sintered at a temperature less than the melting point of aluminum, i.e., 660.23° C., to form a 3D aggregate of sintered aluminum nanoparticles on a first conductive plate, which overlies a silicon semiconductor substrate with a m.p.=1414° C.

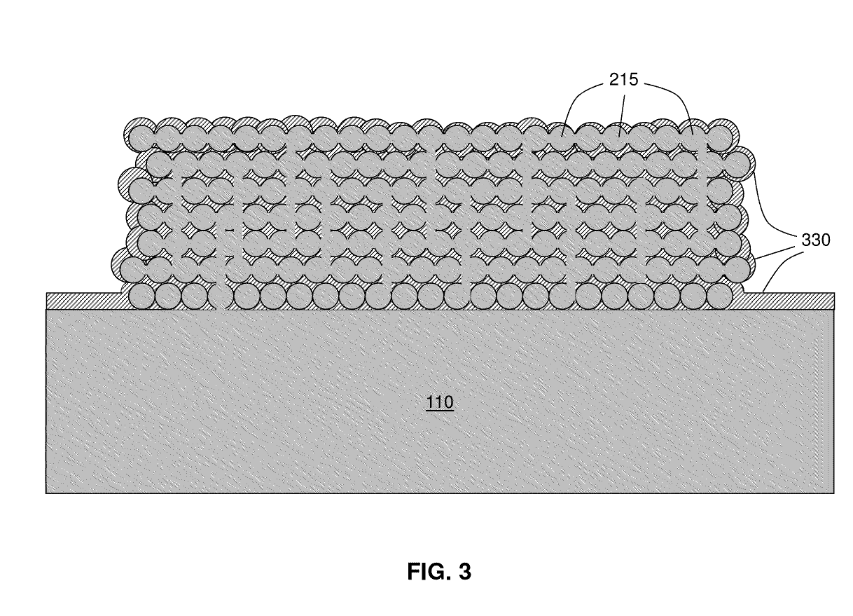

Referring to FIG. 3, in making the supercapacitor, a dielectric 330 of the supercapacitor may be formed on surfaces of the sintered metal nanoparticles 215 and on portions of a top surface of the first conductive plate 110 not physically connected to an overlying sintered metal nanoparticle. Thus, the dielectric 330 forms a continuous layer covering the surfaces of the 3D aggregate of sintered metal nanoparticles 215 and portions of the top surface of the first conductive plate 110 not physically connected to an overlying sintered metal nanoparticle. The thickness of the dielectric 330 may range from 20 Å to 50 Å. The dielectric 330 may comprise an oxide resulting from one of: chemical oxidation and electrochemical anodization of the surfaces of the sintered metal nanoparticles 215 and portions of the top surface of the first conductive plate 110 not physically connected to an overlying sintered metal nanoparticle in making a discrete supercapacitor component. The highest values of capacitance per unit volume, i.e., approaching, equal to or greater than 1 F/cm³, may be attained by using the smaller sizes of metal nanoparticles 115 and a thinner dielectric 330.

Alternatively, a high-k dielectric, e.g., silicon oxide, silicon nitride, or silicon oxynitride, may be deposited at a temperature less than the melting points of the sintered metal nanoparticles 215 and the first conductive plate 110 by chemical vapor deposition on the substrate surfaces of the sintered metal nanoparticles 215 and of portions of the top surface of the first conductive plate 110 not physically connected to an overlying sintered metal nanoparticle in making a discrete supercapacitor or a supercapacitor component of a semiconductor device or in a back end of line (BEOL) process for a semiconductor device.

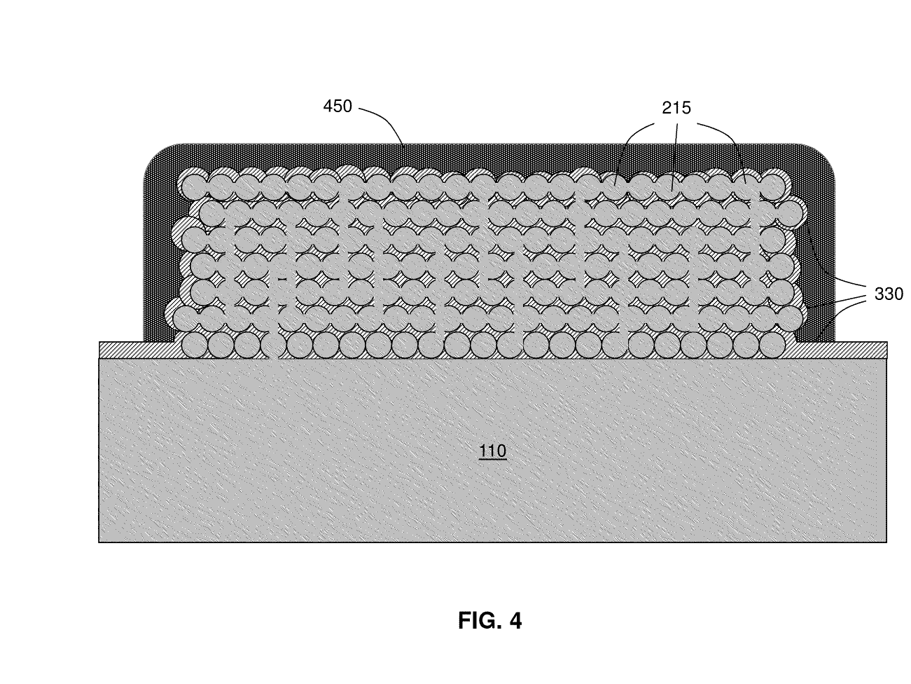

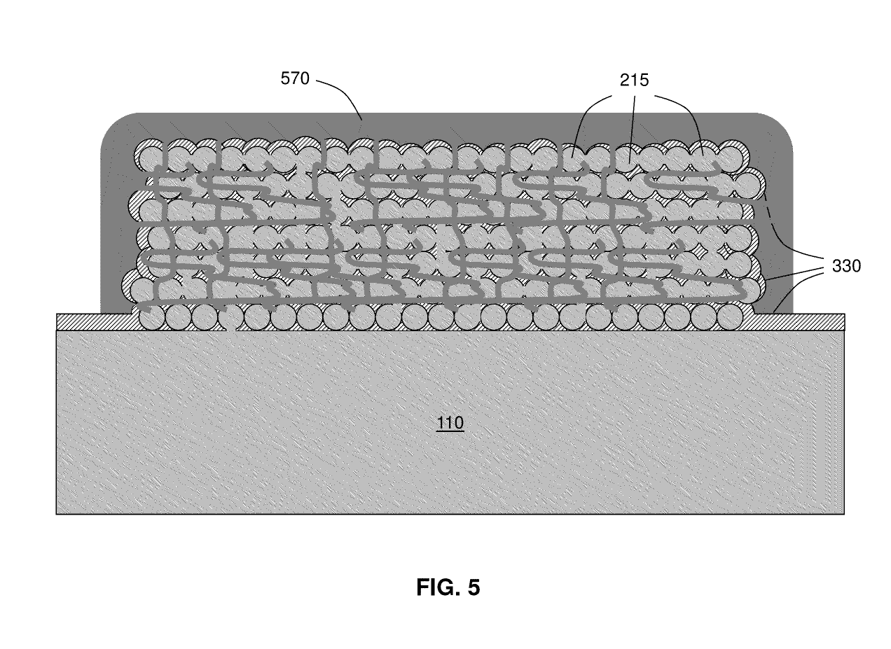

Referring to FIG. 4, in making the supercapacitor, a second conductive plate 450 may be formed on an outermost portion of the dielectric 330. For example, a second conductive plate 450 of tin (Sn), m.p.=231.93° C., may be formed on a dielectric 330 of aluminum oxide (Al₂O₃), m.p.=2072° C., sintered aluminum nanoparticles, m.p.=660.23° C., and a first conductive plate of aluminum, m.p.=660.23° C. If the melting point of the second conductive plate 450 is less than the melting points of the dielectric 330, the sintered metal nanoparticles 215, and the first conductive plate 110, then FIG. 5 illustrates the result of melting the second conductive plate 450, which upon cooling fills the interstices between surfaces of the dielectric 330 and electrically connects to the overlying melted second conductive plate, forming a solid second conductor 570, as the second electrode of the supercapacitor. In the case of making a supercapacitor component of a semiconductor device or in a back end of line (BEOL) process for a semiconductor device, the second conductive plate 450 may comprise semiconductor compatible metals and metal alloys including any of: aluminum (Al), copper (Cu), silver (Ag), titanium (Ti), tantalum (Ta), tin (Sn), nickel (Ni), and tungsten (W).

Returning to FIG. 3, the solid second conductor 570, as shown in FIG. 5, may be formed by injection molding of a metal or solder paste, with a melting point less than the melting points of the dielectric 330, the sintered metal nanoparticles 215, and the first conductive plate 110, into an outermost portion of the dielectric 330. The metal or solder paste, upon cooling, may fill the interstices between surfaces of the dielectric 330 and may cover an outermost portion of the dielectric 330, as shown in FIG. 5, forming the solid second conductor 570, as the second electrode of the supercapacitor. The metal paste may comprise one of: a tin (Sn) paste and an indium (In) paste, and the solder paste may comprise one of: lead (Pb)-free tin solder paste and lead (Pb)-free indium solder paste. The solid second conductor 570 may also be formed by injection molding of a conductive plastic, with a melting point less than the melting points of the dielectric 330, the sintered metal nanoparticles 215, and the first conductive plate 110, to fill interstices between surfaces of the dielectric 330 and to cover the outermost portion of the dielectric 330. Upon cooling, the injected conductive plastic may form the solid second conductor 570, as the second electrode of the supercapacitor.

Returning to FIG. 3, a solid second conductor 570, as shown in FIG. 5, may also be formed by chemical vapor deposition that fills interstices between surfaces of the dielectric 330 and covers an outermost portion of the dielectric 330, to form the solid second conductor 570, forming the second electrode of a discrete supercapacitor or a supercapacitor component in a semiconductor device or in a back end of line (BEOL) process for a semiconductor device. As temperatures for the chemical vapor deposition of a metal on a substrate may be much less than the melting point for the metal, metals with a melting point higher than or equal to any of: the dielectric 330, the sintered metal nanoparticles 215, and the first conductive plate 110, may be deposited by chemical vapor deposition to form the second solid conductor 570. For example, a discrete supercapacitor or a supercapacitor component of a semiconductor device including a first conductive plate 110 of aluminum, m.p.=660.23° C., sintered aluminum nanoparticles 215, m.p.=660.23° C., and a dielectric 330 of aluminum oxide, m.p.=2072° C., may have a solid second conductor 570 formed by chemical vapor deposition of copper (Cu) at a substrate deposition temperature of about 400° C., in contradistinction to the 1084° C. melting point of copper, between the surfaces of the dielectric 330 and covering an outermost portion of the dielectric 330. In the case of making a supercapacitor component of a semiconductor device or in a back end of line (BEOL) process for a semiconductor device, the solid second conductor 570 may comprise semiconductor compatible metals and metal alloys including any of: aluminum (Al), copper (Cu), silver (Ag), titanium (Ti), tantalum (Ta), tin (Sn), nickel (Ni), and tungsten (W).

Referring to FIG. 5, the structure of the supercapacitor may comprise a first electrode comprising a first conductive plate 110 and a 3-dimensional (3D) aggregate of sintered metal nanoparticles 215 disposed above the first conductive plate 110. Each of the sintered metal nanoparticles may retain a similar shape and may be electrically connected one to another and to the first conductive plate 110. The supercapacitor may also comprise a dielectric 330 formed on surfaces of the 3D aggregate of sintered metal nanoparticles and on a top surface of the first conductive plate 110. The supercapacitor may further comprise a second electrode comprising a solid second conductor 570 that fills interstices between surfaces of the dielectric 330, and a second conductive plate of the solid second conductor 570 disposed above an outermost portion of the dielectric 330.

The making of a supercapacitor, as described above, may provide a capacitance per unit volume approaching 1 F/cm³, with small metal nanoparticles and a thin dielectric, resulting from the large surface area of the 3D aggregate of sintered metal nanoparticles in a small volume. The plates and the dielectric of the supercapacitor, described above, comprise solid materials and do not employ a liquid electrolyte as does a conventional double-layer electrochemical supercapacitor or most electrolytic capacitors. Multiple discrete supercapacitors, made by the processes described above, may store large values of electrical charge in parallel arrays for electric power management, electric cars, laptops, etc. The relatively small charge time of the supercapacitor, described above, may allow its use as a battery replacement. Furthermore, the supercapacitor, described above, does not rely upon an electrochemical reaction during charging, as does the conventional double layer electrochemical supercapacitor; hence, the capacitance and the leakage current of the supercapacitor, described above, is relatively insensitive to temperature, bias dependence, and time dependence.

In contrast, the electrical movement of charge in the conventional double layer electrochemical (DLE) supercapacitor occurs with a chemical reaction. This chemical reaction and consequently, the capacitance and the series resistance of the DLE supercapacitor, is highly dependent upon temperature and time. As a result of this temperature sensitivity, safe operation of the conventional DLE supercapacitor is restricted to a narrow temperature range. In addition, the time dependence of the chemical reaction in the conventional DLE supercapacitor affects the leakage current, such that, a lowest leakage current may not occur for hours after an initial voltage bias is applied. Furthermore, a conventional DLE supercapacitor is usually restricted to one polarity of operation, because reversal of the bias terminals may lead to self-destruction.

The making of supercapacitors, with charge storage values approaching, equal to or greater than 1 F/cm³, may provide increased semiconductor integrated circuit densities by decreasing the footprint of, for example, the capacitor of a single bit of dynamic random access memory (DRAM) or the capacitor in a back end of line (BEOL) process for a semiconductor device.

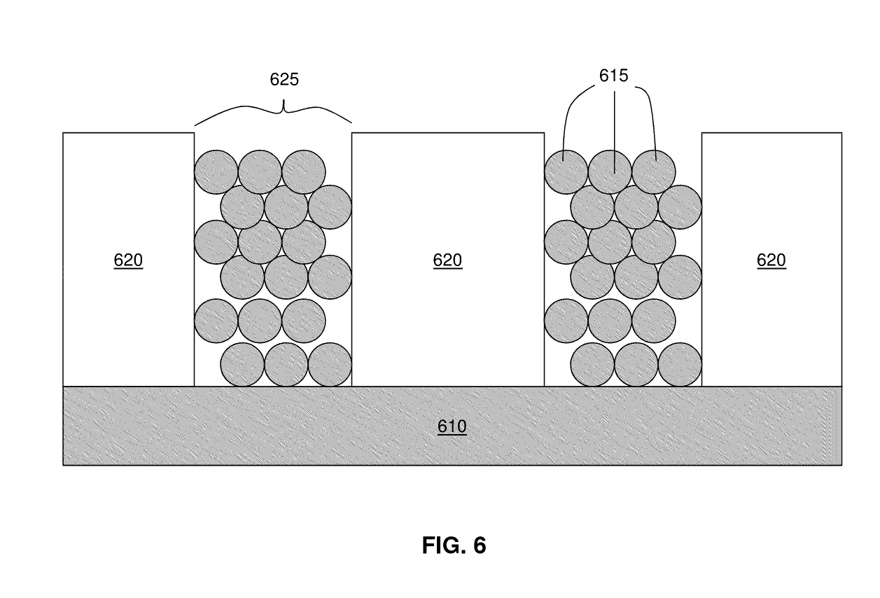

FIGS. 6-9 illustrate a method of making a supercapacitor, having a capacitance per unit volume approaching, equal to or greater than 1 F/cm³, that may use doped silicon (Si) nanoparticles as a conductors to form a portion of a first electrode of the supercapacitor.

Referring to FIG. 6, the method of making a supercapacitor using doped Si nanoparticles 615 may include etching a trench 625 through a silicon oxide (SiO₂) layer 620 to a top surface of a doped Si substrate 610, and filling the trench 625 with doped Si nanoparticles 615 of the same composition as that of the doped Si substrate 610. The doped Si nanoparticles 615 may have roughly similar shapes including any one of: spheres, ellipsoids, rods, cubes, and polyhedrons, and may have a longest axis ranging from 5 nm to 50 nm in length. The dopant of the doped Si substrate 610 and the doped Si nanoparticles 615 may be of either charge-type and may comprise one of: boron (B), arsenic (As), and phosphorus (P).

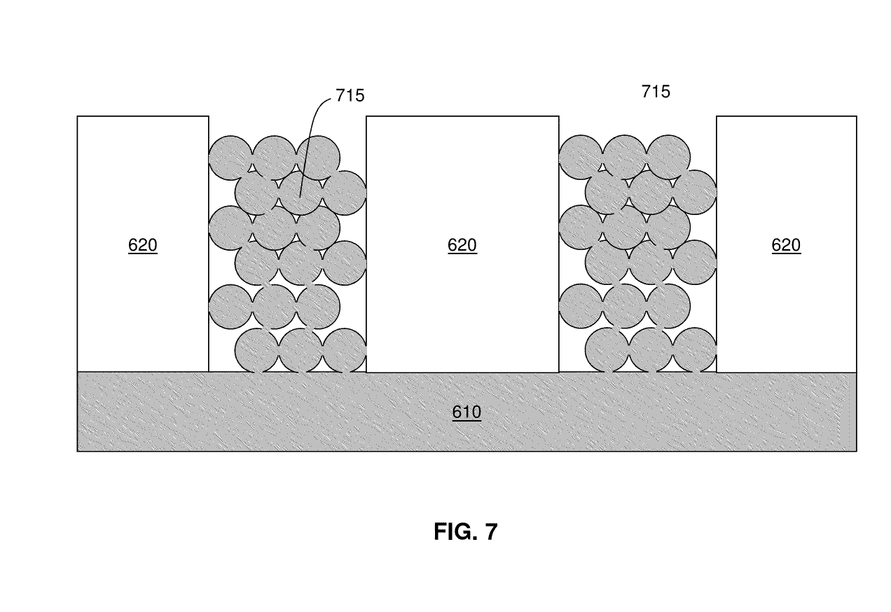

Referring to FIG. 7, the making of a supercapacitor using doped Si nanoparticles 615 may include annealing the doped Si nanoparticles 615 in a hydrogen atmosphere to form a 3-dimensional (3D) aggregate of annealed doped Si particles 715, in which each of the annealed doped Si nanoparticles 715 retains a shape similar to that which was deposited in the trench 625. The 3D aggregate of annealed doped Si nanoparticles 715 may connect physically and electrically from one annealed doped Si nanoparticle to another to the doped Si substrate 610, forming a first electrode of the supercapacitor. Thus, multiple 3D aggregates of annealed doped Si nanoparticles 715 in corresponding trenches 625 may be electrically connected in parallel to the doped Si substrate 610 of the first electrode of the supercapacitor.

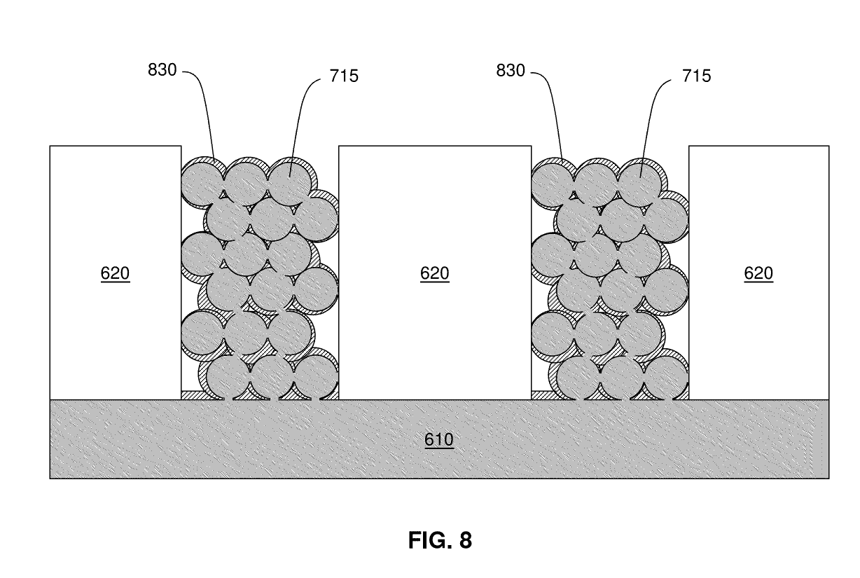

Referring to FIG. 8, the making of the supercapacitor using doped Si nanoparticles 615 may include forming an oxide dielectric 830 by any of thermal oxidation and various chemical vapor deposition processes of oxides on surfaces of the annealed doped Si nanoparticles 715 and on portions of a top surface of the doped Si substrate 610 not physically connected to an overlying anneal doped Si nanoparticle. Thus, the oxide dielectric 830 may form a continuous layer covering the surfaces of the 3D aggregate of annealed doped Si nanoparticles 715 and portions of the top surface of the first doped Si substrate 610 not physically connected to an overlying annealed doped Si nanoparticle. The thickness of the oxide dielectric 830 may range from 14 Å to 30 Å at 1.2 volts and may be proportionately thicker at higher voltages. The highest values of capacitance per unit volume, i.e., approaching, equal to or greater than 1 F/cm³, may be attained by using the smaller sizes of doped Si nanoparticles 615 and a thinner oxide dielectric 830.

Alternatively, a high-k dielectric, e.g., silicon nitride, or silicon oxynitride, may be deposited at a temperature less than that for annealing of the annealed doped Si nanoparticles 615 by chemical vapor deposition on the substrate surfaces of the annealed doped Si nanoparticles 715 and of portions of the top surface of the doped Si substrate 610 not physically connected to an overlying annealed doped Si nanoparticle.

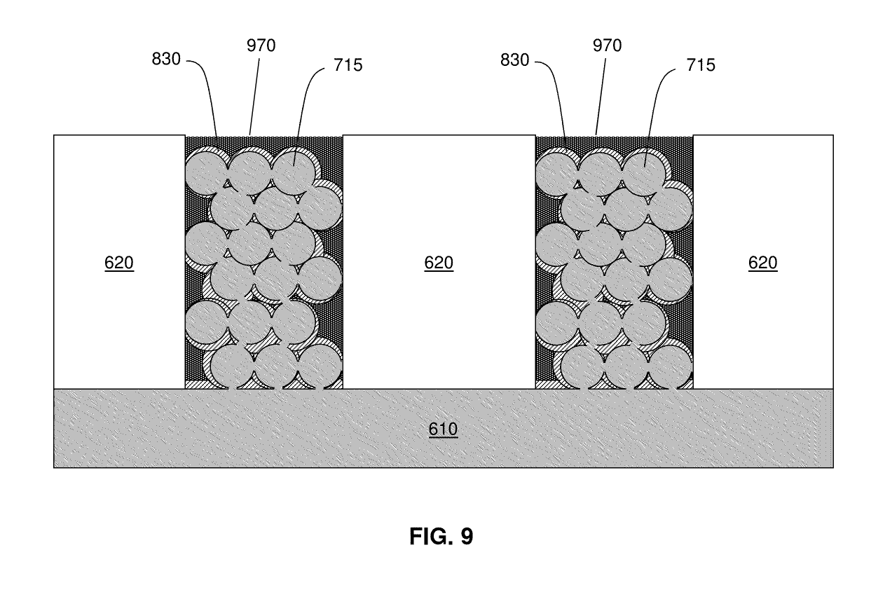

Referring to FIG. 9, the making of the supercapacitor using doped Si nanoparticles 715 may include depositing, by chemical vapor deposition, a doped Si to fill interstices between surfaces of the oxide dielectric 830 and to cover a top portion of the oxide dielectric 830 between the walls of the trench 625, forming a solid second conductor 970, as the second electrode of the supercapacitor. The temperatures for chemical vapor deposition of the doped Si, forming the solid second conductor 970, may be much less than the melting points of the walls of the trench 625, the oxide dielectric 830, the annealed doped Si nanoparticles 715, and the doped Si substrate 610. The dopant of the doped Si forming the solid second conductor 970 may be of either charge-type and may comprise one of: boron (B), arsenic (As), and phosphorus (P). Portions of the SiO₂ layer 620 may separate individual supercapacitors, which are electrically connected in parallel by the doped Si substrate 610, as shown in FIG. 9.

Referring to FIG. 9, the structure of the supercapacitor, made be the processes described immediately above, may comprise a first electrode comprising the doped Si substrate 610 and a 3-dimensional (3D) aggregate of annealed doped Si nanoparticles 715 disposed above the doped Si substrate 610. Each of the annealed doped Si nanoparticles 715 may retain a similar shape and may be electrically connected one to another and to the doped Si substrate 610. The supercapacitor may also comprise an oxide dielectric 830 formed on surfaces of the 3D aggregate of annealed doped Si nanoparticles 715 and on a top surface of the doped Si substrate 610. The supercapacitor may further comprise a second electrode comprising a solid second conductor 970 that fills interstices between surfaces of the oxide dielectric 830, and a second conductive plate of the solid second conductor 570 disposed above an outermost portion of the oxide dielectric 830.

The making of a supercapacitor using doped Si nanoparticles, as described above, may provide a capacitance per unit volume approaching, equal to or greater than 1 F/cm³ with smaller doped Si nanoparticles and a thinner oxide dielectric resulting from the large surface area of the 3D aggregate of annealed doped Si nanoparticles in a small volume. The plates and the dielectric of the supercapacitor using doped Si nanoparticles comprise solid materials and do not employ a liquid electrolyte as does a conventional double-layer electrochemical supercapacitor or most electrolytic capacitors. Multiple supercapacitors using doped Si nanoparticles that are electrically connected in parallel may store large values of electrical charge for electric power management, electric cars, laptops, etc. The relatively small charge time of the supercapacitor using doped Si nanoparticles may allow its use as a battery replacement. The supercapacitor using doped Si nanoparticles may offer comparatively low intrinsic current leakage and temperature insensitivity over normal operating conditions, when compared to conventional double-layer electrochemical supercapacitors.

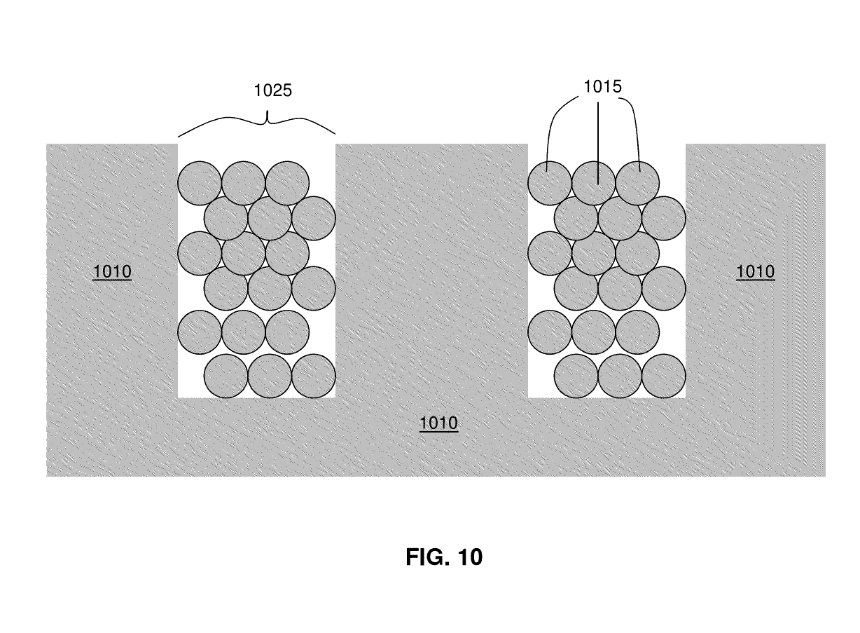

FIGS. 10-13 illustrate an alternative method of making a supercapacitor, having a capacitance per unit volume approaching, equal to or greater than 1 F/cm³ in some cases, which may use doped silicon (Si) nanoparticles as conductors to form a portion of a first electrode of the supercapacitor.

Referring to FIG. 10, the method of making a supercapacitor using doped Si nanoparticles 1015 may include etching a trench 1025 into a doped Si substrate 1010, and filling the trench 1025 with the doped Si nanoparticles 1015 of the same composition as that of the doped Si substrate 1010. The doped Si nanoparticles 1015 may have roughly similar shapes including any one of: spheres, ellipsoids, rods, cubes, and polyhedrons, and may have a longest axis ranging from 5 nm to 50 nm in length. The dopant of the doped Si substrate 1010 and the doped Si nanoparticles 1015 may be of either charge-type and may comprise one of: boron (B), arsenic (As), and phosphorus (P).

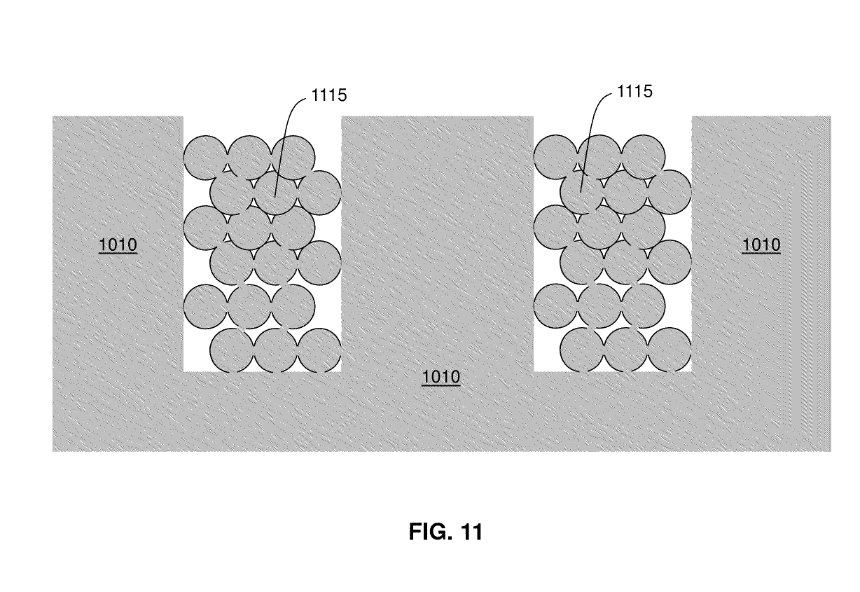

Referring to FIG. 11, the making of a supercapacitor using doped Si nanoparticles 1015 may include annealing the doped Si nanoparticles 1015 in a hydrogen atmosphere to form a 3-dimensional (3D) aggregate of annealed doped Si particles 1115, in which each of the annealed doped Si nanoparticles 1115 retains a shape similar to that which was deposited in the trench 1025. The 3D aggregate of annealed doped Si nanoparticles 1115 may connect physically and electrically from one annealed doped Si nanoparticle to another to the doped Si substrate 1010, forming a first electrode of the supercapacitor. Thus, multiple 3D aggregates of annealed doped Si nanoparticles 1115 in corresponding trenches 1025 may be electrically connected in parallel to the doped Si substrate 1010 of the first electrode of the supercapacitor.

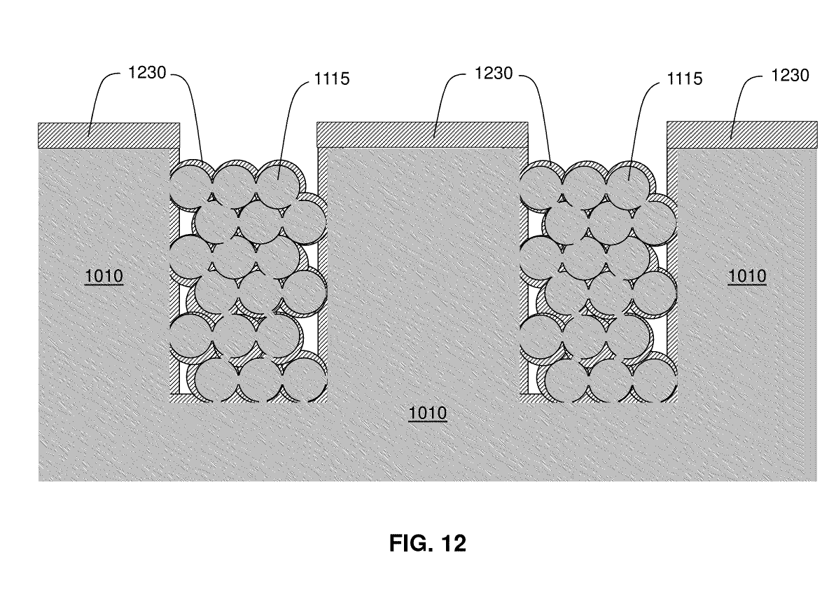

Referring to FIG. 12, the making of the supercapacitor using doped Si nanoparticles 1015 may include forming an oxide dielectric 1230 by any of thermal oxidation and various chemical vapor deposition processes of oxides on surfaces of the annealed doped Si nanoparticles 1115, on a top surface of the doped Si substrate 1010, and on portions of sidewalls and a bottom surface of the trench 1025 not physically connected to an adjacent anneal doped Si nanoparticle. Thus, the oxide dielectric 1230 may form a continuous layer covering the surfaces of the 3D aggregate of annealed doped Si nanoparticles 1115, a top surface of the doped Si substrate 1010, and portions of sidewalls and a bottom surface of the trench 1025 not physically connected to an adjacent anneal doped Si nanoparticle. The thickness of the oxide dielectric 1230 may range from 14 Å to 30 Å at 1.2 volts and may be proportionately thicker at higher voltages. The highest values of capacitance per unit volume, i.e., approaching, equal to or greater than 1 F/cm³, may result from using the smaller doped Si nanoparticles 1015 and a thinner oxide dielectric 1230.

Alternatively, a high-k dielectric, e.g., silicon nitride, or silicon oxynitride, may be deposited at a temperature less than that for annealing of the annealed doped Si nanoparticles 1115 by chemical vapor deposition on the substrate surfaces of the annealed doped Si nanoparticles 1115, on a top surface of the doped Si substrate 1010, and on portions of sidewalls and a bottom surface of the trench 1025 not physically connected to an adjacent anneal doped Si nanoparticle.

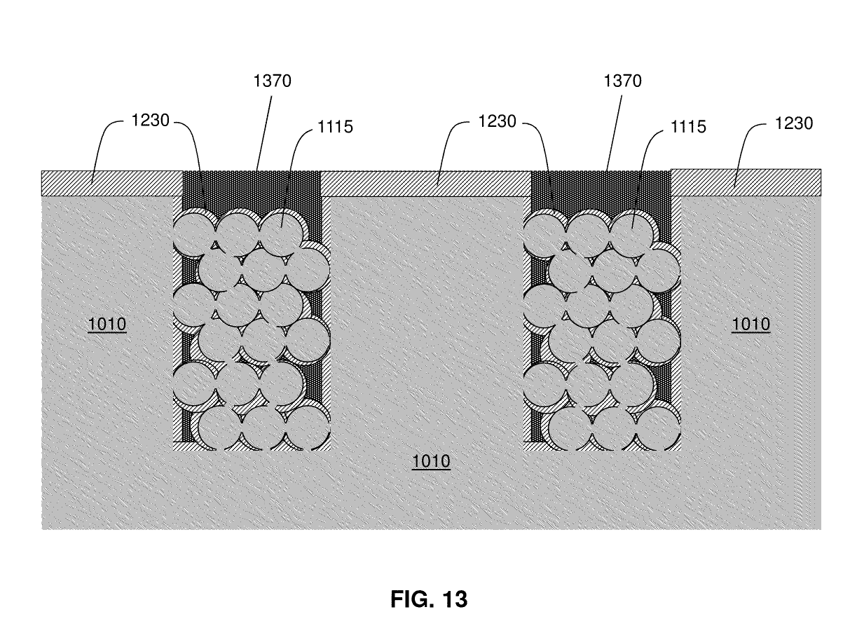

Referring to FIG. 13, the making of the supercapacitor using doped Si nanoparticles 1015 may include depositing, by chemical vapor deposition, a doped Si to fill interstices between surfaces of the oxide dielectric 1230 and to cover a top portion of the oxide dielectric 1230 located between the walls of the trench 1025, forming a solid second conductor 1370, as the second electrode of the supercapacitor. The temperatures for chemical vapor deposition of the doped Si, forming the solid second conductor 1370, may be much less than the melting points of the walls of the trench 1025, the oxide dielectric 1230, the annealed doped Si nanoparticles 1115, and the doped Si substrate 1010. The dopant of the doped Si forming the solid second conductor 1370 may be of either charge-type and may comprise one of: boron (B), arsenic (As), and phosphorus (P). Alternatively, the solid second conductor 1370 may be formed by chemical vapor deposition of a metal. Referring to FIG. 13, the structure of the supercapacitor, made be the processes described immediately above, may comprise a first electrode comprising the doped Si substrate 1010 and a 3-dimensional (3D) aggregate of annealed doped Si nanoparticles 1115 disposed in a trench formed in the doped Si substrate 1010. Each of the annealed doped Si nanoparticles 1115 may retain a similar shape and may be electrically connected one to another and to the doped Si substrate 1010. The supercapacitor may also comprise an oxide dielectric 1230 formed on surfaces of the 3D aggregate of annealed doped Si nanoparticles 1115 and on a top surface of the doped Si substrate 1010, and on portions of sidewalls and a bottom surface of the trench 1025 not physically connected to an adjacent anneal doped Si nanoparticle. The supercapacitor may further comprise a second electrode comprising a solid second conductor 1370 that fills interstices between surfaces of the oxide dielectric 1230, and a second conductive plate of the solid second conductor 1370 disposed above an outermost portion of the oxide dielectric 1230 located between sidewalls of the trench 1025.

The making of a supercapacitor using doped Si nanoparticles, as described above, may provide a capacitance per unit volume equal to or greater than 1 F/cm³ with smaller doped Si nanoparticles and a thinner oxide dielectric resulting from the large surface area of the 3D aggregate of annealed doped Si nanoparticles in a small volume. The plates and the dielectric of the supercapacitor using doped Si nanoparticles comprise solid materials and do not employ a liquid electrolyte as does a conventional double-layer electrochemical supercapacitor or most electrolytic capacitors. Multiple supercapacitors using doped Si nanoparticles that are electrically connected in parallel may store large values of electrical charge for electric power management, electric cars, laptops, etc. The relatively small charge time of the supercapacitor using doped Si nanoparticles may allow its use as a battery replacement. The supercapacitor using doped Si nanoparticles may offer comparatively low intrinsic current leakage and temperature insensitivity over normal operating conditions, when compared to conventional double-layer electrochemical supercapacitors.

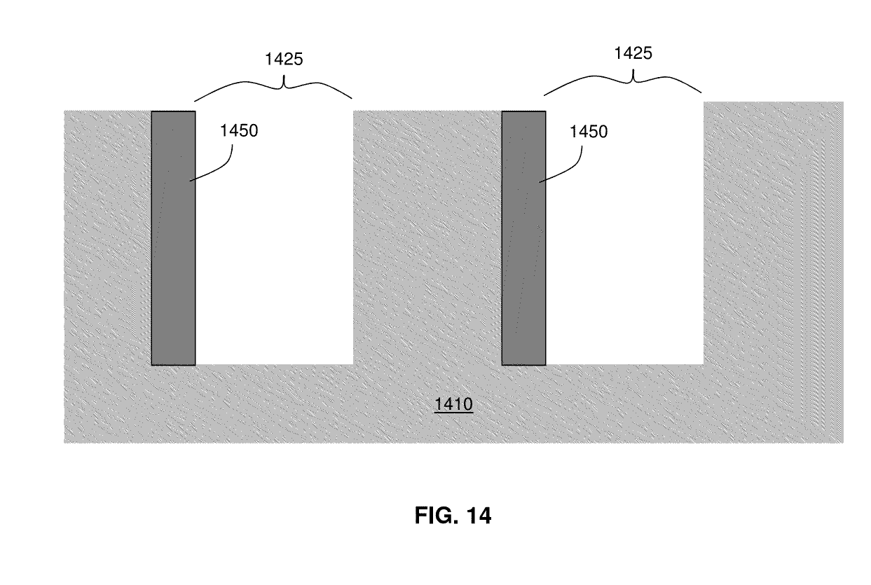

FIGS. 14-16 illustrate a method of making a diode in a semiconductor integrated circuit that may use a mixture of doped Si nanoparticles of a first charge-type and of a second-charge type. The small size of the doped Si nanoparticles and the mixture of the two charge-types may provide upon annealing, merging and reflow, an intermingled 3-dimensional (3D) region of doped Si of the first charge-type and doped Si of the second charge-type that has a very large opposing surface area in a small volume.

Referring to FIG. 14, the method of making a diode in a semiconductor integrated circuit may include etching a trench 1425 within a doped silicon (Si) substrate 1410 of a first charge-type, and forming a sidewall 1450 on the trench 1425 with doped Si of a second charge-type.

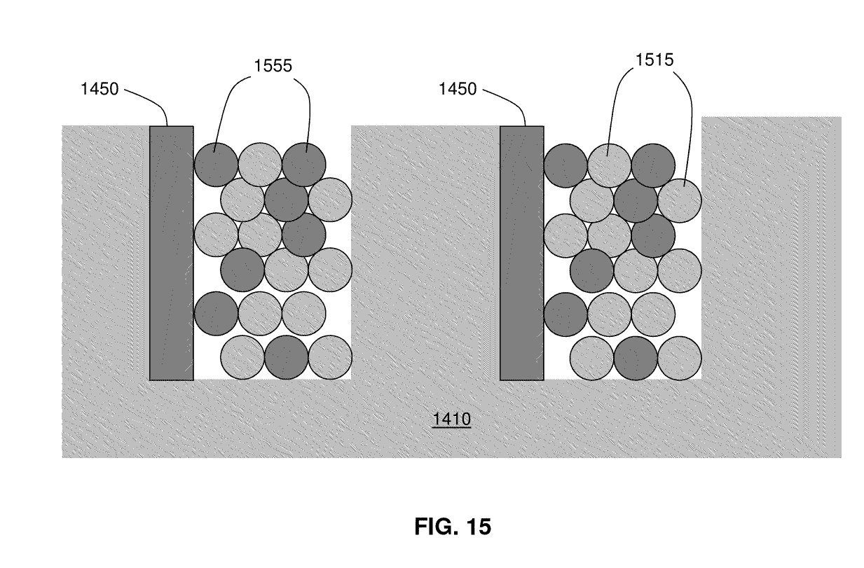

Referring to FIG. 15, the method of making a diode in a semiconductor integrated circuit may include filling the trench 1425 with the sidewall 1450 with a mixture of doped Si nanoparticles of a first charge-type 1515 and of a second charge-type 1555. The doped Si nanoparticles of the first charge-type 1515 and of the second charge-type 1555 may have roughly similar shapes including any one of: spheres, ellipsoids, rods, cubes, and polyhedrons, and may have a longest axis ranging from 5 nm to 50 nm in length. The dopant of the doped Si nanoparticles of the first charge-type 1515 and the doped Si substrate 1410 may comprise boron (B), while the dopant of the doped Si nanoparticles of the second charge-type 1555 and the sidewall 1450 may comprise one of arsenic (As) and phosphorus (P). Alternatively, the dopant of the doped Si nanoparticles of the first charge-type 1515 and the doped Si substrate 1410 may comprise one of As and P, while the dopant of the doped Si nanoparticles of the second charge-type 1555 and the sidewall 1450 may comprise B.

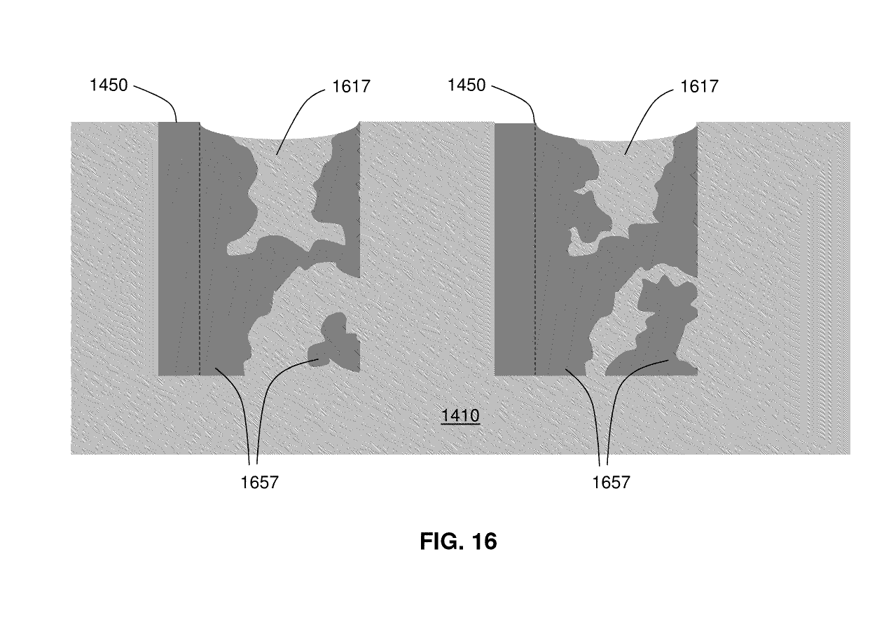

Referring to FIG. 16, the method of making a diode in a semiconductor integrated circuit may include annealing and reflowing the mixture of the doped Si nanoparticles of the first charge-type 1515 and of the second charge-type 1555 to form the intermingled 3D region of annealed, reflowed doped Si of the first charge-type 1617 and annealed, reflowed doped Si of the second charge-type 1657. In this annealing, reflowing and merging of the doped Si nanoparticles of the first charge-type 1515 and of the second charge-type 1555, the nanoparticles reflow and merge, losing their shapes and sizes, to form the intermingled 3D region of annealed, reflowed doped Si of the first charge-type 1617 and annealed, reflowed doped Si of the second charge-type 1657. The intermingled 3D region may include: a first 3D region of the annealed, reflowed doped Si of the first charge-type 1617 electrically connected to the doped Si substrate 1410 of the first charge-type and a second 3D region of the annealed, reflowed doped Si of the second charge-type 1657 electrically connected to the sidewall 1450 of the second charge-type. The intermingled 3D region may also include a surface, forming a p-n junction, between the first 3D region of the annealed, reflowed doped Si of the first charge-type 1617 and the second 3D region of the annealed, reflowed doped Si of the second charge-type 1657. Terminal leads for the diode may be formed on top surfaces of the doped Si substrate 1410 and the sidewall 1450 of the second charge-type, respectively.

Referring to FIG. 16, the structure of the diode, as described by the processes immediately above, may comprise a trench region 1425 disposed within a doped silicon (Si) substrate 1410 of a first charge type, in which a sidewall 1450 of a second charge-type is formed in the trench region 1425. An intermingled 3D region may be disposed within the trench region 1425. The intermingled 3D region may include a first 3D region of the annealed, reflowed doped Si of the first charge-type 1617 electrically connected to the doped Si substrate 1410 of the first charge-type and a second 3D region of the annealed, reflowed doped Si of the second charge-type 1657 electrically connected to the sidewall 1450 of the second charge-type. The intermingled 3D region may also include a surface, forming a p-n junction, between the first 3D region of the annealed, reflowed doped Si of the first charge-type 1617 and the second 3D region of the annealed, reflowed doped Si of the second charge-type 1657. Terminal leads for the diode may be formed on top surfaces of the doped Si substrate 1410 and the sidewall 1450 of the second charge-type, respectively.

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A supercapacitor, comprising:
a first electrode comprising a first conductive plate and a 3-dimensional (3D) aggregate of sintered nanoparticles disposed above said first conductive plate, each of said sintered nanoparticles retaining a similar shape and electrically connecting one to another and to said first conductive plate;
a dielectric formed on surfaces of said 3D aggregate of sintered nanoparticles and on said first conductive plate; and
a second electrode comprising a solid second conductor filling interstices between surfaces of said dielectric and electrically connecting to a second conductive plate of said solid second conductor disposed above an outermost portion of said dielectric.

2. The supercapacitor of claim 1, said dielectric having a thickness ranging from 14 Å to 50 Å.

3. The supercapacitor of claim 1, said first conductive plate comprising aluminum (Al), said sintered nanoparticles comprising Al, and each of said sintered nanoparticles of said similar shape having a longest axis ranging from 5 nm to 50 nm.

4. The supercapacitor of claim 1, said solid second conductor having a melting point less than that of said first electrode and of said dielectric.

5. The supercapacitor of claim 1, said 3D aggregate of sintered nanoparticles comprising one of a metal and a metal alloy including any of: aluminum (Al), copper (Cu), silver (Ag), titanium (Ti), tantalum (Ta), nickel (Ni), and tungsten (W).

6. The supercapacitor of claim 1, said dielectric may comprise an oxide on said surfaces of said 3D aggregate of sintered metal nanoparticles 215 and portions of said first conductive plate 110 not physically connected to an overlying sintered metal nanoparticle.

7. The supercapacitor of claim 1, said second electrode comprising one of a metal and a metal alloy including any of: tin (Sn), aluminum (Al), copper (Cu), silver (Ag), titanium (Ti), tantalum (Ta), nickel (Ni), and tungsten (W).

8. The supercapacitor of claim 1 formed in a semiconductor integrated circuit (IC) by semiconductor IC processes using one of semiconductor compatible metals and semiconductor compatible metal alloys for said 3D aggregate of sintered nanoparticles and said second electrode.

9. A method of making a supercapacitor in a semiconductor integrated circuit, comprising:
etching a trench through an oxide layer to a top surface of a doped silicon (Si) substrate;
filling said trench with doped Si nanoparticles of the same composition as said doped Si substrate;
annealing said doped Si nanoparticles to form a 3-dimensional (3D) aggregate of annealed doped Si nanoparticles, each of said annealed doped Si nanoparticles retaining a similar shape and electrically connecting one to another to said top surface of said doped Si substrate, forming a first electrode;
forming an oxide dielectric on a surface of said 3D aggregate of said annealed doped Si nanoparticles and on portions of said top surface of said doped Si substrate; and
depositing a chemical vapor of Si and a dopant to fill interstices between surfaces of said oxide dielectric with doped Si and to form a layer of said doped Si on a top portion of said oxide dielectric between walls of said trench, forming a solid second conductor, as a second electrode of said supercapacitor.

10. The method of claim 9, prior to etching said trench, forming said oxide layer on said top surface of said doped Si substrate.

11. The method of claim 9, a dopant of said doped Si substrate and said annealed doped Si nanoparticles, forming said first electrode, comprising one of: a positive charge-type comprising boron (B), and a negative charge-type further comprising one of arsenic (As) and phosphorus (P).

12. The method of claim 9, said forming an oxide dielectric by one of thermal oxidation and various CVD deposition processes on said surface of said 3D aggregate of said annealed doped Si nanoparticles and on said portions of said top surface of said doped Si substrate.

13. The method of claim 9, said depositing said chemical vapor of Si and said dopant to form said solid second conductor being less than melting points of walls of said trench, said oxide dielectric, said annealed doped Si nanoparticles, and said doped Si substrate.

14. The method of claim 9, a dopant of said solid second conductor, forming said second electrode, comprising one of: a positive charge-type comprising boron (B), and a negative charge-type further comprising one of arsenic (As) and phosphorus (P).

15. The method of claim 9, further connecting electrically in parallel a plurality of first electrodes from each of a plurality of supercapacitors to said doped Si substrate.

16. The method of claim 9, each of said doped Si nanoparticles having a similar shape and a longest axis ranging from 5 nm to 50 nm.

17. A method of making a diode in a semiconductor integrated circuit, comprising:
etching a trench within a doped silicon (Si) substrate of a first charge-type;
forming a sidewall on said trench with doped Si of a second charge-type;
filling said trench with said sidewall with a mixture of first doped Si nanoparticles of said first charge-type and of second doped Si nanoparticle of said second charge-type; and
annealing and reflowing said mixture of said first doped Si nanoparticles and said second doped Si nanoparticles, to form:
a first 3-dimensional (3D) region of annealed, reflowed doped Si of said first charge-type electrically connected to said doped Si substrate,
a second 3D region of annealed, reflowed doped Si of said second charge-type electrically connected to said sidewall, and
a first surface portion of said first 3D region of said annealed, reflowed doped Si of said first charge-type being annealed and electrically connected to a second surface portion of said second 3D region of said annealed, reflowed doped Si of said second-charge type, forming a p-n junction of said diode.

18. The method of claim 17, said first doped Si nanoparticles of said first charge-type and said second doped Si nanoparticles of said second charge-type comprising roughly similar shapes including any one of: spheres, ellipsoids, rods, cubes, and polyhedrons, and having a longest axis ranging from 5 nm to 50 nm in length.

19. The method of claim 17, said annealing and reflowing causing said first doped Si nanoparticles and said second doped Si nanoparticles to lose their shapes and sizes to form an intermingled 3D region forming said p-n junction between said first 3D region of annealed, reflowed doped Si of said first charge-type and said second 3D region of said annealed, reflowed doped Si of the second charge-type.

20. The method of claim 17, further comprising forming terminal leads of said diode on top surfaces of said doped Si substrate of said first charge-type and of said sidewall on said trench with said doped Si of said second charge-type, respectively.
